(19) United States
(12) Patent Application Publication
(10) Pub. No.: US 2024/0422936 A1
(43) Pub. Date: Dec. 19, 2024

(54) EXHAUST AIRFLOW DIRECTION CONTROL

(71) Applicant: PLUME DESIGN, INC., Palo Alto, CA (US)

(72) Inventors: Ming-Tsung SU, Taipei City (TW); Chun-Wen WANG, Taoyuan City (TW); Chun Hung LIU, Taipei City (TW); Yu-Ting HUANG, Hsinchu City (TW)

(21) Appl. No.: 18/336,601

(22) Filed: Jun. 16, 2023

(51) Int. Cl. H05K 7/20

(52) U.S. Cl. CPC H05K 7/20145

(57) ABSTRACT

An air flow redirection system for redirecting exhaust air flow away from an external surface upon which the device is positioned, the device may include a housing including a first side, a second side opposite the first side, at least one sidewall extending between the first side and second side, a vent, the vent defining an opening extending through the at least one sidewall placing an interior chamber of the device in fluid communication with an exterior region, at least one rib defining slots in the vent, and an arc. Air flow produced by a fan located in the interior chamber is directed towards the vent in a first direction, and the arc acts in combination with the at least one rib and raises a direction of the air flow upward in a second direction towards a plane of the first side as the air flow exits the vent.

### FIELD

The present disclosure relates to the field of fan assemblies. More particularly, to exhaust airflow direction control.

### BACKGROUND

Fan assemblies are used in a variety of applications for directing air onto or away from heat sources, such as electrical components, to provide cooling and to prevent overheating. Typically, a device that includes fan(s) for providing air circulation includes one or more vents on the device housing. However, the device may be operated in an environment with pollutants in the air. Accordingly, the fan blowing the air out of the housing vent can cause dust to collect on surfaces near the exhaust vent upon which the device is located.

### SUMMARY

A device may include a housing including a first side, a second side opposite the first side, at least one sidewall extending between the first side to the second side, a vent, the vent defining an opening extending through the at least one sidewall placing an interior chamber of the device in fluid communication with an exterior region, at least one rib, the at least one rib defining slots in the vent extending across a length of the vent, and an arc, an air flow produced by a fan located in the interior chamber is directed towards the vent in a first direction, and the arc acts in combination with the at least one rib and raises a direction of the air flow upward in a second direction towards a plane of the first side as the air flow exits the vent.

In some embodiments, the housing further includes: a ramp, the ramp defining a sloping transition to the arc along a bottom surface of the interior chamber to enable the air flow to interact with the arc.

In some embodiments, the ramp aligns with the arc to form a continuously sloping transition with the arc.

In some embodiments, the housing further includes a chamfer located at the vent adjacent the exterior region and the chamfer enables the air flow exiting the vent to be directed upward in the second direction away from the second side.

In some embodiments, the at least one sidewall includes a plurality of sidewalls extending between the first side and the second side.

In some embodiments, the vent extends in a horizontal direction relative to the first side and the second side.

In some embodiments, the at least one sidewall defines the at least one rib and is integrally formed with the at least one sidewall and the vent.

In some embodiments, the second direction is not parallel to the first direction.

In some embodiments, the housing is configured to be positioned onto an external surface such that the second side is adjacent the external surface.

In some embodiments, an exhaust air flow direction control system for a device having a housing, a fan, and one or more heat generating components being cooled by the fan, the exhaust air flow direction control system including a vent, the vent defining an opening extending through at least one sidewall of the housing, the vent placing an interior chamber of the device in fluid communication with an exterior region, an arc, the arc being located between the vent and the interior chamber of the device, a plurality of ribs, the plurality of ribs defining slots therebetween formed at the vent, and a ramp, the ramp defining a sloping transition formed along a bottom surface of the interior chamber, and the fan directs an air flow in a first direction towards the vent, and the arc acts in combination with the plurality of ribs and raises a direction of the air flow upward in a second direction towards a plane of a first side of the device as the air flow exits the vent.

In some embodiments, the ramp aligns with the arc to form a continuously sloping transition with the arc to enable the air flow directed in the first direction to interact with the arc and rises in the second direction towards the plurality of ribs and the plane of the first side.

In some embodiments, the arc integrally formed with the vent at the at least one sidewall.

In some embodiments, a system, further including a chamfer located at the vent adjacent the exterior region and the chamfer enables the air flow exiting the vent to be directed upward in the second direction away from a second side.

In some embodiments, the at least one sidewall angularly extends in an outward direction as the at least one sidewall extends from the second side and towards the first side such that a first area defined by the first side is greater than a second area defined by the second side.

In some embodiments, the exhaust vent extends in a horizontal direction relative to the first side and the second side.

In some embodiments, the at least one sidewall defines the plurality of ribs such that the plurality of ribs is integrally formed with the at least one sidewall.

In some embodiments, the second direction is not parallel to the first direction.

In some embodiments, the device is configured to be positioned onto an external surface such that the second side is adjacent the external surface, and the second direction is angled away from a plane of the external surface.

In some embodiments, a system includes a fan, one or more heat generating electrical components, a housing including a first side, a second side, and at least one sidewall extending between the first side and the second side, the at least one sidewall defines an interior chamber of the housing. In some embodiments, the system further includes a vent, the vent extending through the at least one sidewall and places the interior chamber in fluid communication with an exterior region, a plurality of ribs, the plurality of ribs defining a plurality of slots therebetween at the vent, an arc, the arc being integrally formed with the vent adjacent the interior chamber, a ramp, the ramp defining a sloping transition aligned with the arc along a bottom surface of the interior chamber, and a chamfer, the chamfer being located in the vent and is defined by the at least one sidewall. The arc, plurality of ribs, ramp, and chamfer act in combination to direct an air flow moving in a first direction through the interior chamber to be redirected in a second direction away from a plane of the first side as the air passes through the vent.

In some embodiments, the air flow directed through the vent is moved upward relative the first direction by the arc and the air flow bounces off the plurality of ribs and exits the vent in the second direction towards a plane of the first side, the first direction and the second direction are not parallel.

### DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a partial perspective view of a non-limiting example embodiment of a device, according to some embodiments.

FIG. 2 is a side view of the device, according to some embodiments.

FIG. 3 is an exposed side view of the device, according to some embodiments.

FIG. 4 is a second exposed side view of the device, according to some embodiments.

FIG. 5 is an exposed side view of the device, according to some embodiments.

FIG. 6 is an exposed side view of the device, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Fan operations within a housing of a device for cooling heat generating components can draw in pollutants, such as dust, present in the external environment into the housing, which can then be exhausted out through a vent of the device. As a result of static forces, the exhaust air flow can cause dust trails to collect on surfaces located near the vent, particularly when the air flow is directed towards a direction of the adjacent surface. A user of the device that observes the dust collecting at the vent may interpret such an occurrence as being caused by faulty operation or by an issue with the electrical components within the device, thereby raising concerns in users about the safety and reliability of the device when the device may be functioning as expected.

Various embodiments of the present disclosure relate to systems, devices, and/or assemblies that include one or more distinctive structural features or structural characteristics at or near a vent for controlling a direction of the cooling air being exhausted out from within an interior space to an exterior environment such that the cooling air flows in a direction pointed away from an external surface located adjacent the vent. For example, the device may be configured to be mounted onto a surface, such as onto a wall, and the device may include a vent that exhausts cooling air flow produced by the fan away from the surface such as to prevent pollutants in the air from collecting on the surface near the device and the vent. Various embodiments of the present disclosure may relate to a device having a housing that defines an opening, thereby forming the vent through which the cooling air may be directed out of during the fan's operation.

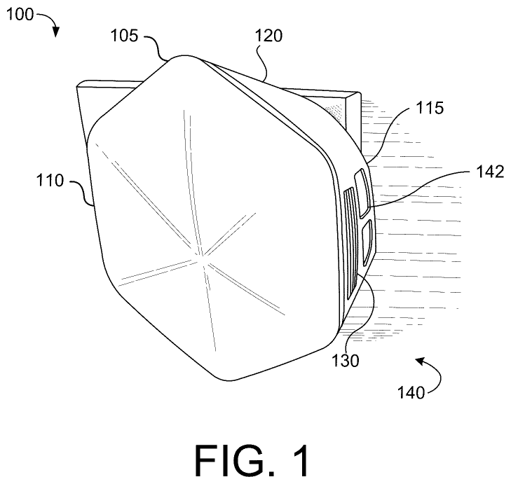

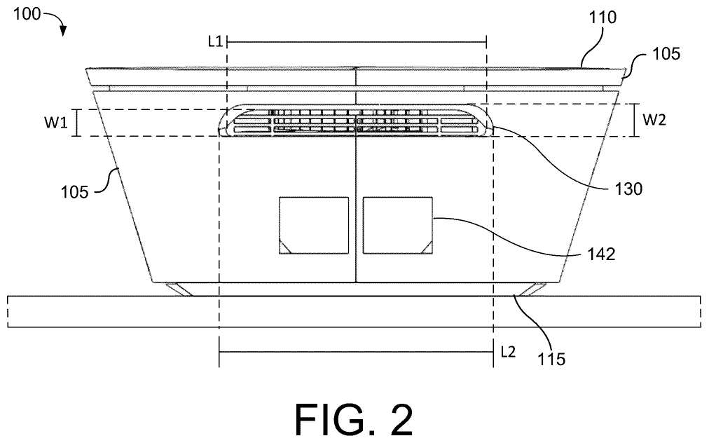

FIG. 1 is a perspective view of a device 100, according to some embodiments. FIG. 2 is a side view of the device 100, according to some embodiments. Unless otherwise specified, FIGS. 1 and 2 will be described collectively.

Device 100 may include a housing 105 having a first side 110 and a second side 115 opposite the first side 110. The housing 105 may include a sidewall 120 extending between the first side 110 and second side 115. In some embodiments, the housing 105 may include at least one sidewall 120 extending between the first side 110 and second side 115. In other embodiments, the housing 105 may include a plurality of sidewall 120 extending between the first side 110 and second side 115. Additionally, the housing 105 may include one or more members that form the housing 105. For example, the housing 105 may include a first member and a second member which may be fixedly attached together to form the housing 105. It is to be appreciated by those having ordinary skill in the art that the housing 105 may include one or more members (e.g., parts) and is not intended to be limiting. It is also to be appreciated by those having ordinary skill in the art that the device 100 and the housing 105 may include one or more sidewall 120 extending between the first side 110 to the second side 115 and is not intended to be limiting.

The device 100 may include one or more components located within the housing 105 that generate heat as a result of operation. For example, the device 100 may include one or more electrical components that produce heat as a result of operation. The device 100 may include a fan 125 located within the housing 105 for cooling the one or more components by driving air circulation in the interior of the device 100. In another example, the device 100 may be a modem for providing WIFI within a range of the device 100 and include a fan 125 located therein for cooling the electronic components located therein.

The device 100 may include a vent 130 for allowing cooling air circulating within the housing 105 as a result of operation of the fan 125 to be drawn in and/or out of the housing 105. The housing 105 may define the vent 130, in some embodiments. Additionally, the vent 130 may extend between the first side 110 and the sidewall 120, such as in a horizontal direction relative to the first side 110 and sidewall 120, as shown in FIG. 2. In some embodiments, the vent 130 may extend through the sidewall 120 of the housing 105. For example, the vent 130 may be an opening formed at the sidewall 120 on the housing 105 of the device 100. In some embodiments, the device 100 may include at least one vent 130. In other embodiments, the device 100 may include a plurality of vent 130. For example, the device 100 may include a first vent and a second vent oppositely arranged on the at least one sidewall 120 of the housing 105.

The housing 105 may include a first member and second member, in some embodiments. In some embodiments, the device 100 may include a first vent defined by the first member and a second vent defined by the second member. In some embodiments, each of the first member and the second member may include a cutout portion arranged at respective ends thereof such that when the first member and second member are fixedly attached together the respective cutouts align and form the vent 130. In other embodiments, the first member and second member may have formed thereon cutouts arranged at each end thereof such that when fixedly attached together they form a first and second vent 130. In some embodiments, the first vent 130 and second vent 130 may both be exhausts for cooling air to be directed out of the device 100 to the exterior region 140. In other embodiments, the first vent 130 may be an inlet and the second vent 130 may be an exhaust.

The vent 130 may have dimensions defined by a length L and a width W. The vent 130 may be arranged in a longitudinal direction with respect to the first side 110 and second side 115 such that the length of the vent 130 may be substantially parallel with the respective planes of the first side 110 and second side 115, in some embodiments. Stated another way, in some embodiments, the vent 130 may circumferentially extend along the sidewall 120. In some embodiments, the length L of the vent 130 may be greater than the width W. For example, the vent 130 may be 6 cm (L)×1 cm (W). In another example, the dimensions of the vent 130 may be 3 cm (L)×1 cm (W). In yet another example, the dimensions of the vent 130 may be 4 cm (L)×2 cm (W). In other embodiments, the length L of the vent 130 may be substantially equal the width L. For example, the dimensions of the vent 130 may be 4 cm (L)×4 cm (W). In other embodiments, the length L of the vent 130 may be less than the width W. For example, the vent 130 may be 3 cm (L)×4 cm (W). It is to be appreciated by those having ordinary skill in the art that the dimensions of the device 100, housing 105, vent 130, and the structural features for controlling the direction of air flow are not intended to be limiting unless otherwise specified and may include any of a plurality of dimensions such that exhaust air from within the device 100 may be directed outward in accordance with the present disclosure.

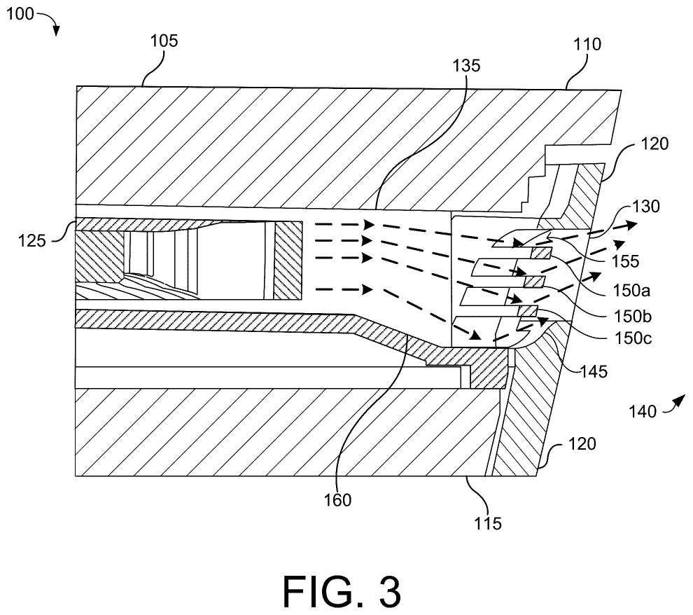

The vent 130 may include dimensions such that the length L and width W of the vent 130 gradually increases as the vent 130 extends from the interior chamber 135 towards the exterior region 140 through the sidewall 120. The vent 130, as shown in FIG. 2, may include dimensions defined as a first length L1 and a first width W1 near the interior chamber 135, in some embodiments. Additionally, the vent 130 may also include dimensions defined as a second length L2 and a second width W2 near the exterior region 140, in some embodiments. The cross-sectional area of vent 130 may increase as the vent 130 extends from the interior chamber 135 and towards the exterior region 140 to enable the air flowing through vent 130 to be directed in an upward direction, as viewed relative to FIG. 3, towards a plane of the first side 110 and away from a plane of the second side 115. The air is therefore directed away from the second side 115, which corresponds to the side on which the device 100 is placed when positioned (or mounted) onto the external surface and the respective side which may thereby abut the external surface, to enable the exhaust air to be directed away from the external surface when the device 100 is placed onto (or mounted onto) the external surface. In other embodiments, the dimensions of vent 130 may be substantially uniform as the vent 130 extends through the sidewall 120.

In some embodiments, the device 100 may include an air inlet 142. The air inlet 142 enables air to flow into the interior chamber 135 for cooling the one or more heat generating components in device 100. In some embodiments, the cooling air may be drawn through air inlet 142 into the device 100 by operation of the fan 125, such that the air flow may cool the components and may be exhausted out the vent 130. In some embodiments, the device 100 may include one or more air inlet 142. For example, the device 100 may include a first air inlet 142 and second air inlet 142. In some embodiments, the interior chamber 135 may include a lower chamber and an upper chamber, and the fan 125 may draw the air into the lower chamber through air inlet 142, through the heat generating components, through the upper chamber, and out the vent 130.

FIG. 3 is an exposed side view of the device 100, according to some embodiments.

The device 100 includes one or more structural features therein that affects an air flow direction, e.g., exhaust air flow, such that the air flowing from the interior chamber 135 and passing through the vent 130 to the exterior region 140 may be redirected in an upward direction relative its original direction to reduce the likelihood of pollutants in the air, such as dust, debris, or other contaminants, accumulating on the external surface upon which the device 100 is positioned or attached. In some embodiments, the direction of the air flow approaching the vent 130 from in the interior chamber 135 may be perpendicular to the vent 130. In other embodiments, the direction of the air flow approaching the vent 130 from in the interior chamber 135 may be substantially perpendicular to the vent 130. However, it is to be appreciated by those having ordinary skill in the art that the direction of the air flow as it approaches vent 130 from the interior chamber 135 is not intended to be limiting and the air flow direction may be perpendicular relative to the vent 130 opening or may be angular relative to the vent 130 opening. In this regard, it is to be appreciated by those having ordinary skill in the art that the direction of air flow relative to the vent 130 opening is not intended to be limiting and that the one or more features of the device 100 may be configured to alter the direction of the air flowing from the interior chamber 135 and passing through the vent 130 to direct the air flow away from the external surface upon which the device 100 is positioned, in accordance with the present disclosure.

Accordingly, the device 100 may include vent 130, arc 145, and rib 150. Vent 130 forms an opening which places the interior chamber 135 in fluid communication with the exterior region 140 to enable air flow to be directed out of the device 100. The vent 130 may extend through the sidewall 120, thereby placing the interior chamber 135 of device 100 containing a fan 125 in fluid communication with the exterior region 140. In some embodiments, the vent 130 may also be referred to as an exhaust vent for enabling air flow circulating within the housing 105 to be directed out of the interior chamber 135 and to the exterior region 140. In this regard, the interior chamber 135 of the device 100 may include any of a plurality of dimensions suitable for enabling the fan 125 to direct air flow onto or across one or more heat generating components to provide thermal heat exchange with the components and such that the cooling air may then be directed radially outward relative to a central axis of the device 100 and/or relative the central axis of fan 125, and through the vent 130.

The device 100 may include a plurality of vent 130 for enabling cooling air to be drawn into and out of the device 100 for cooling the interior chamber 135 and the one or more heat generating components located therein, in some embodiments. For example, in some embodiments, the device 100 may include a first and second vent 130, the first or second vent 130 being configured to serve as an inlet for cooling air to be drawn into the interior chamber 135 by the fan 125 for cooling the heat generating components and the other of the first and second vent 130 being configured to serve as an outlet for cooling air to be directed out of from the interior chamber 135 by virtue of the operation of the fan 125.

The device 100 may include an arc 145. The arc 145 interacts with the exhaust air moving in the outward direction, thereby causing the air flow to rise in an upward direction toward the plane of the first side 110 relative to its original direction. The arc 145 may be located between the interior chamber 135 and the vent 130 and may define an upwardly sloping surface forming a transition between a bottom surface of the interior chamber 135 to the vent 130 opening respectively. The arc 145 may be located in the interior chamber 135 adjacent the vent 130. In some embodiments, the arc 145 may be defined by the sidewall 120. As such, the arc 145 may be integrally formed with the vent 130 at the sidewall 120. In other embodiments, the arc 145 may be defined by the bottom surface of the interior chamber 135.

The device 100 may include rib 150. In some embodiments, and as shown in FIG. 3, the device 100 includes rib 150a, rib 150b, rib 150c, hereinafter referred to as rib 150. The rib 150 provides a bouncing effect when the air flow goes through the rib 150, which thereby acts as a stepping-stone for the air to bounce up. In this regard, the rib 150 further enables the air flow to rise in the upward directions towards the plane of the first side 110. The rib 150 also define slots 155 formed at the vent 130 between the rib 150 and another one of the rib 150 or the vent 130. An air flow produced by a fan 125 (e.g., fan blade) may be directed in the outward direction towards the vent 130, and the arc 145 may act in combination with the rib 150 to raise a direction of the air flow at an upward angle relative to the outward direction and towards the first side 110, so that the air flow is redirected from a first direction to a second direction as the air flow exits the vent 130. In this regard, the direction of the air flow moving through the interior chamber 135 and towards the vent 130 is not parallel with the direction of the air flow passing through the vent 130 and out of the vent 130 at the exterior region 140.

The rib 150 may be located at the vent 130 opening adjacent the interior chamber 135 and longitudinally extend across the length L of vent 130. In some embodiments, the rib 150 may be located in vent 130. In some embodiments, the sidewall 120 may define the rib 150 at the vent 130. In this regard, the rib 150 may be integrally formed with the sidewall 120, in some embodiments. In some embodiments, the device 100 may include a plurality of rib 150. In some embodiments, the device 100 may include one or more rib 150. In other embodiments, the device 100 may include a plurality of rib 150.

In some embodiments, the rib 150 may be arranged such that they are substantially parallel with the plane of the first side 110 and second side 115. In other embodiments, the rib 150 may be angular with respect to the plane of the first side 110 and second side 115, such that the angularly extend in an upward direction to promote the air flow to be raised upward as the air flow moves out the vent 130.

In some embodiments, the device 100 may further include a ramp 160. The ramp 160 may be defined by a bottom surface of the interior chamber 135 and forms a sloping transition to the arc 145. The ramp 160 enables the air flow to move towards and interact with the arc 145 so that the air flow may interact with the arc 145 and to enable the air flow to rise upwards towards the plane of the first side 110. Additionally, the ramp 160 may be formed such as to align with the arc 145 to provide a continuously extending transition to enable the air flow to interact with the arc 145 and to promote the air flow to rise upwards.

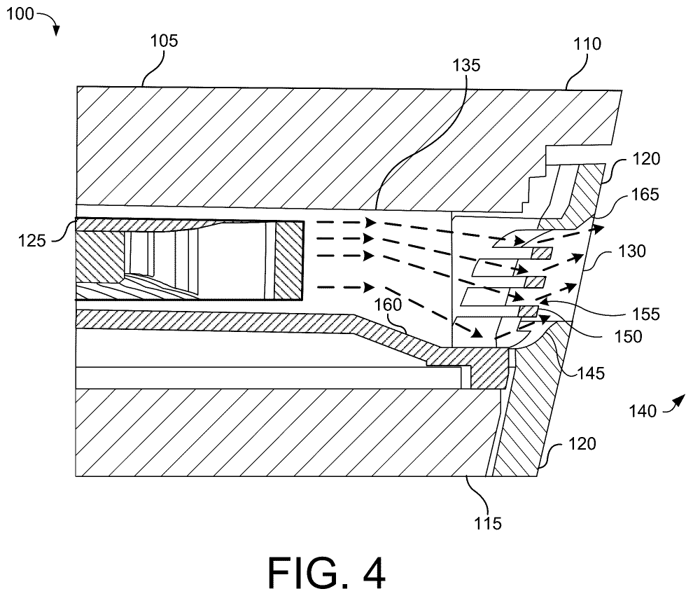

FIG. 4 is a second exposed side view of the device 100, according to some embodiments.

The device 100 may also include a chamfer 165. The chamfer 165 may be formed at the vent 130 adjacent the exterior region 140. The chamfer 165 enables the air flow moving in the upward direction as a result of interacting with the arc 145 and the rib 150, to continue to freely move in the upward direction towards the plane of the sidewall 120. In this regards, the chamfer 165 includes dimensions suitable for enabling the air flow to bounce upwards from the rib 150 and move upwards out the vent 130 and thereby reduces the amount of air flow that may then interact with the upper portion of vent 130 and reduce the amount of air flow that moves in the upwards direction. The chamfer 165 may be defined by the sidewall 120, in some embodiments. As shown in FIG. 4, the chamfer 165 angularly extends in the upward direction at the vent 130. However, FIG. 4 is for illustrative purposes and is not intended to be limiting and the vent 130 and the corresponding features, such as chamfer 165, may include any of a plurality of dimensions suitable for enabling the air flow to be directed away from the external surface upon which the device 100 is placed, in accordance with the present disclosure. For example, in some embodiments, the chamfer 165 may form a sloping transitioning surface the extends in the upward direction such that the width of the vent 130 at the interior chamber 135 is smaller than the width adjacent the exterior region 140.

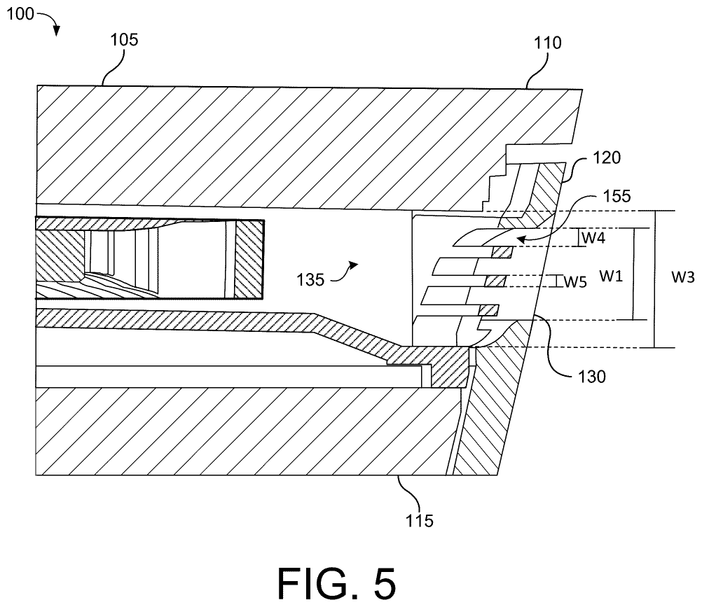

FIG. 5 is a third exposed side view of the device 100, according to some embodiments.

The device 100 may be designed such as to maximize a width W3 of the interior chamber 135 relative to the first width W1 associated with the vent 130. Stated another way, the width W3 of the interior chamber 135 may be greater than the width W1 of the vent 130 opening. Maximizing the width W3 of the interior chamber 135 relative to the width W1 of vent 130 enables the device 100 to maintain airflow efficiency, airflow volume (CFM), and velocity of the air flow being exhausted from the interior chamber 135 to the exterior region 140.

The slot 155 at the vent 130 openings, e.g., the space between adjacent ribs 150 and between rib 150 and a periphery of vent 130 may be a width W4, the width being determined based on a safety regulation/requirement. In some embodiments, the width W4 of the slot 155 may be approximately 1 mm. In some embodiments, the width W4 of slot 155 may be 1 mm or less. In other embodiments, the width W4 of slot 155 may be a maximum of 1 mm.

Additionally, each of the rib 150 may include a width W5. In some embodiments, the width W5 of each rib 150 may be based on a plastic injection limitation. As such, the one or more components of device 100 may be made of any of a plurality of injection molded plastics. In some embodiments, the rib 150 may include a width W5 from 0.6 mm to 0.7 mm, or any range, or subrange therebetween. In other embodiments, the rib 150 may include a width W5 of at least 0.6 mm. In yet other embodiments, the rib 150 may include a width W5 of less than 0.7 mm.

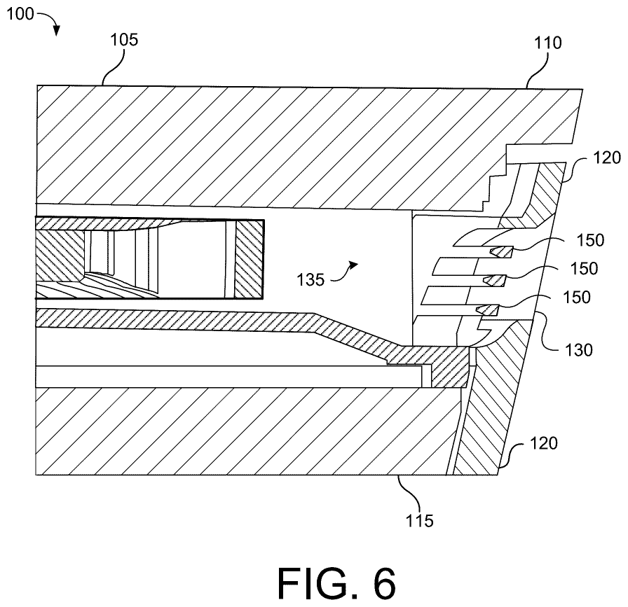

FIG. 6 is an exposed side view of the device 100, according to some embodiments.

The vent 130 may include one or more rib 150 located therein. Each rib 150 may extend in a longitudinal direction across a length of the vent 130. Additionally, as shown at FIG. 6, each rib 150 may be defined by a tapered profile, where a width of the rib 150 at a side facing the interior chamber 135 is narrower than a width of the rib 150 at a side facing the exterior region 140. In this regard, each of the rib 150 may increase in width as the length of the rib 150 extends from the interior chamber 135 to the exterior region 140.

Each of the rib 150 may include a narrower width at the side facing the interior chamber 135 such as to enhance the airflow blowing out of the vent 130 through the rib 150 and to minimize the amount of dust and debris that may gather at each of the rib 150. In this regard, a greater surface area at the side of the rib 150 adjacent the interior chamber may cause a greater amount of dust or debris to gather on each of the rib 150, whereas a narrower width reduces the likelihood of debris or dust collecting onto the rib 150. Moreover, dust gathering on the rib 150 may result in downgrades in thermal dissipation performance at the device 100 over long periods of time.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

### [ZOT—Definition of Terms—Use as Needed]

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements; disposed indirectly between both of the two other structural elements such that the particular structural component is not in direct contact with both of the two other structural elements, and other features can be disposed therebetween; or any combination(s) thereof.

As used herein “embedded” means that a first material is distributed throughout a second material.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A device comprising:
a housing comprising:
a first side;
a second side opposite the first side;
at least one sidewall extending between the first side to the second side;
a vent,
wherein the vent defines an opening extending through the at least one sidewall placing an interior chamber of the device in fluid communication with an exterior region;
at least one rib,
wherein the at least one rib defines slots in the vent extending across a length of the vent; and
an arc;
wherein an air flow produced by a fan located in the interior chamber is directed towards the vent in a first direction, and the arc acts in combination with the at least one rib and raises a direction of the air flow upward in a second direction towards a plane of the first side as the air flow exits the vent.

2. The device of claim 1, wherein the housing further comprises:
a ramp,
wherein the ramp defines a sloping transition to the arc along a bottom surface of the interior chamber to enable the air flow to interact with the arc.

3. The device of claim 2, wherein the ramp aligns with the arc to form a continuously sloping transition with the arc.

4. The device of claim 1, wherein the housing further comprises:
a chamfer,
wherein the chamfer is located at the vent adjacent the exterior region and the chamfer enables the air flow exiting the vent to be directed upward in the second direction away from the second side.

5. The device of claim 1, wherein the at least one sidewall comprises a plurality of sidewalls extending between the first side and the second side.

6. The device of claim 1, wherein the vent extends in a horizontal direction relative to the first side and the second side.

7. The device of claim 1, wherein the at least one sidewall defines the at least one rib and is integrally formed with the at least one sidewall and the vent.

8. The device of claim 1, wherein the second direction is not parallel to the first direction.

9. The device of claim 1, wherein the housing is configured to be positioned onto an external surface such that the second side is adjacent the external surface.

10. An exhaust air flow direction control system for a device having a housing, a fan, and one or more heat generating components being cooled by the fan, the exhaust air flow direction control system comprising:
a vent,
wherein the vent defines an opening extending through at least one sidewall of the housing, the vent placing an interior chamber of the device in fluid communication with an exterior region;
an arc,
wherein the arc is located between the vent and the interior chamber of the device;
a plurality of ribs,
wherein the plurality of ribs define slots therebetween formed at the vent; and
a ramp,
wherein the ramp defines a sloping transition formed along a bottom surface of the interior chamber; and
wherein the fan directs an air flow in a first direction towards the vent, and wherein the arc acts in combination with the plurality of ribs and raises a direction of the air flow upward in a second direction towards a plane of a first side of the device as the air flow exits the vent.

11. The system of claim 10, wherein the ramp aligns with the arc to form a continuously sloping transition with the arc to enable the air flow directed in the first direction to interact with the arc and rises in the second direction towards the plurality of ribs and the plane of the first side.

12. The system of claim 10, wherein the arc integrally formed with the vent at the at least one sidewall.

13. The system of claim 10, further comprising:
a chamfer,
wherein the chamfer is located at the vent adjacent the exterior region and the chamfer enables the air flow exiting the vent to be directed upward in the second direction away from a second side.

14. The system of claim 10, wherein the at least one sidewall angularly extends in an outward direction as the at least one sidewall extends from the second side and towards the first side such that a first area defined by the first side is greater than a second area defined by the second side.

15. The system of claim 10, wherein the exhaust vent extends in a horizontal direction relative to the first side and the second side.

16. The system of claim 10, wherein the at least one sidewall defines the plurality of ribs such that the plurality of ribs is integrally formed with the at least one sidewall.

17. The system of claim 10, wherein the second direction is not parallel to the first direction.

18. The system of claim 10, wherein the device is configured to be positioned onto an external surface such that the second side is adjacent the external surface, and wherein the second direction is angled away from a plane of the external surface.

19. A system comprising:
a fan;
one or more heat generating electrical components;
a housing comprising:
a first side,
a second side, and
at least one sidewall extending between the first side and the second side,
wherein the at least one sidewall defines an interior chamber of the housing;
a vent,
wherein the vent extends through the at least one sidewall and places the interior chamber in fluid communication with an exterior region;
a plurality of ribs,
wherein the plurality of ribs define a plurality of slots therebetween at the vent,
an arc,
wherein the arc is located is integrally formed with the vent adjacent the interior chamber;
a ramp,
wherein the ramp defines a sloping transition aligned with the arc along a bottom surface of the interior chamber; and
a chamfer,
wherein the chamfer is located in the vent and is defined by the at least one side wall;
wherein the arc, plurality of ribs, ramp, and chamfer act in combination to direct an air flow moving in a first direction through the interior chamber to be redirected in a second direction away from a plane of the first side as the air passes through the vent.

20. The system of claim 19, further comprising:
wherein the air flow directed through the vent is moved upward relative the first direction by the arc and wherein the air flow bounces off the plurality of ribs and exits the vent in the second direction towards a plane of the first side;
wherein the first direction and the second direction are not parallel.
